(19) United States
(12) Patent Application Publication
(10) Pub. No.: US 2003/0111587 A1
(43) Pub. Date: Jun. 19, 2003

(54) Scanning device capable of conducting black calibration with fixed mask

(75) Inventors: Bill Chen, Hsin-Chu (TW); Albert Lu, Hsin-Chu (TW); Jimmy Tsao, Hsin-Chu (TW)

Correspondence Address: LOWE HAUPTMAN GOPSTEIN GILMAN & BERNER, LLP, Suite 310, 1700 Diagonal Road, Alexandria, VA, 22314, US

(73) Assignee: MUSTEK SYSTEMS INC.

(21) Appl. No.: 10/015,570

(22) Filed: Dec. 17, 2001

(51) Int. Cl. H01L 27/00

(52) U.S. Cl. 250/208.1

(57) ABSTRACT

A scanning system capable of conducting black calibration with a fixed mask has a shell, a conveying module for driving an image capture module to a parallel movement, an image capture module for capturing image therefore transferred to digital signals, and a fixed mask for obstructing the light path in order to conduct the black calibration. The image capture module is driven by the conveying module and moved to a predetermined mask position. At the predetermined mask position, the mask may obstruct the light path. In this case, the scanning device is able to conduct the black calibration, provided a black calibration signal for adjustment purposes.

### DESCRIPTION

### BACKGROUND OF THE INVENTION

1. Field of the Invention

The present invention relates to a scanning system capable of conducting a black calibration with a fixed mask.

2. Background Description

In the present technologies of scanning devices, before the scanning, the scanning device needs to conduct the white calibration and the black calibration. The white calibration is designed to confirm the whitest image, after digitalization, becoming the white image calibration signals. Same as the above, the black calibration is designed to confirm the blackest image, after digitalization, becoming the black calibration image signals. These two types of calibration signals are used to do the adjustment of image signal processes.

In an ordinary scanner, the black calibration is conducted by covering the light projected to the dummy pixels of both ends of a CCD (Charged-Coupled Device) to generate the black image calibration signals. However, the output image signals from the CCD would not be the same in a general linear CCD at the same time per pixel. Actually, the output image signals of both ends of the CCD usually are lower than the output image signals generated from the central portion of the CCD. Therefore, if the black calibration image signals are calculated by the average value of the output image signals, the adjustment will cause an incorrect black calibration and thus the color image reflecting the document will be not right.

There is another method for doing the black calibration. Firstly, the light is turned off. The CCD will not capture any light. In this case, every pixel on the CCD may sense the no-light situation and there the black calibration is conducted. However, since the light is turned to do the black calibration right, when the scanning is ongoing, the light is needed to be turned on. It usually takes long time to warm up the light tube in order to get a steady light propagation. Sometimes, the turn-on and warm-up procedures take dozens minutes. This method is not convenient and humanized.

There is yet another method for conducting the black calibration. There is a mask able to move to the light source once the black calibration is needed. The mask is movable. The mask is conveyed to cover the CCD away from the light. When the light is obstructed, the CCD is conducting the black calibration. In this case, every pixel may adjust the black image signal and the light source is no need to be turned off. The method and structure of the inventor's knowledge are shown in the following.

Please refer to FIGS. 2A and 2B. FIG. 2A shows the cross section of the scanner having a automatic masking device. FIG. 2B shows the scanner under the situation that the light is obstructed by the mask which is conveyed to the masking position. The scanner has a shell 21. The shell 21 includes at least a window 26 having a glass for placing a document 25, a driving module 22 which is positioned inside the shell 21, a guiding rod 222, an image capturing module 23, a mask 242 and an automatic conveying module 24. Both ends of the driving module 22 are mounted on the inner face of the shell 21. The driving module 21 has a actuator 221 or a motor for providing the driving force. The image capturing module 23 is connected to the driving module 22 for moving along the guiding rod 222 in parallel in order to capture the image of the document. Later the image is transformed to digital signals. The image capturing module includes a housing 231, a light source 232 for projecting the light, an image sensing element 234 or a CCD for transforming image to digital signals, and plural mirrors for alternating the light into the image sensing element. The automatic conveying module 24 includes the mask 242 for obstructing the light path 232, a conveying mechanism 241 for conveying the mask 242 to a predetermined position in order to obstruct the light including a belt or gear sets, and a actuator (not shown in the Figures).

When conducting the scan as shown in FIG. 2A, the light 235 is propagated from the light source 232. After reflected by the document 25, the image of the document 25 is again reflected by plural mirrors 233 then into the image sensing element 234. Thus, the image sensing element 234 captures the image and generates digital signals. The driving module 23 therefore moves the image sensing element 23 to another position in parallel in order to complete the scan processes.

However, before the scan processes as mentioned in the above, the scanner needed to conduct the black calibration in order to get the image signals adjusted rightfully as shown in FIG. 2B. In this case, the automatic conveying module will move the mask 242 to the predetermined position via the help of the conveying mechanism 241. While the light 235 is propagated from the light source 232 and reflected by the document and mirrors, the light is obstructed and prohibited to enter the pixels of the image sensing element 234. Therefore, the pixels of the image sensing element may capture the standard black color and do the black calibration.

Although in this method, the light is not needed to be turned off to conduct the black calibration, it will still be high cost due to the utilization of another conveying module as long with an existed driving module already. Besides, the assembly, easy maintenance and durability are hardly to achieve.

### SUMMARY OF THE INVENTION

It is therefore an object of the present invention to provide a scanning system capable of generating acoustic notices to users. Thus, the user is fully informed of the status of the scanning processes by the acoustic notices generated by the scanning system. Besides, the acoustic notice is developed to fulfill the enjoyment of using the scanning system when the acoustic notice accompanying with fancy lights.

### BRIEF DESCRIPTION OF THE DRAWINGS

The foregoing and other objects, aspects and advantages will be better understood from the following detailed description of a preferred embodiment of the invention with reference to the drawings, in which:

FIG. 1 shows the chart of the output voltage and the positions of the pixels of the CCD;

FIG. 2A shows the scanner with an automatic conveying module in the scan processes;

FIG. 2B shows the scanner with an automatic conveying module at the position of conducting the black calibration;

FIG. 3A is the present invention conducting the scan processes;

FIG. 3B show the present invention at the position of conducting the black calibration; and

FIG. 4 shows the flow chart of the present invention while conducts the black calibration.

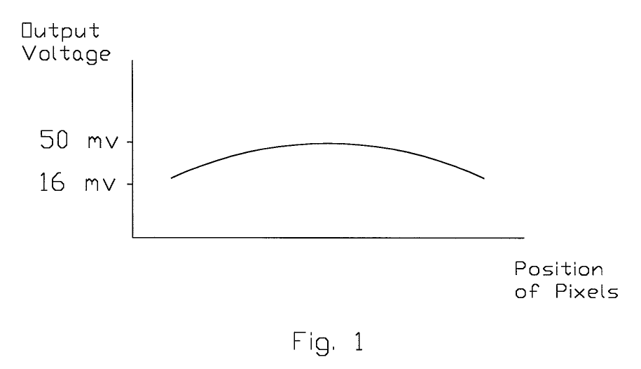

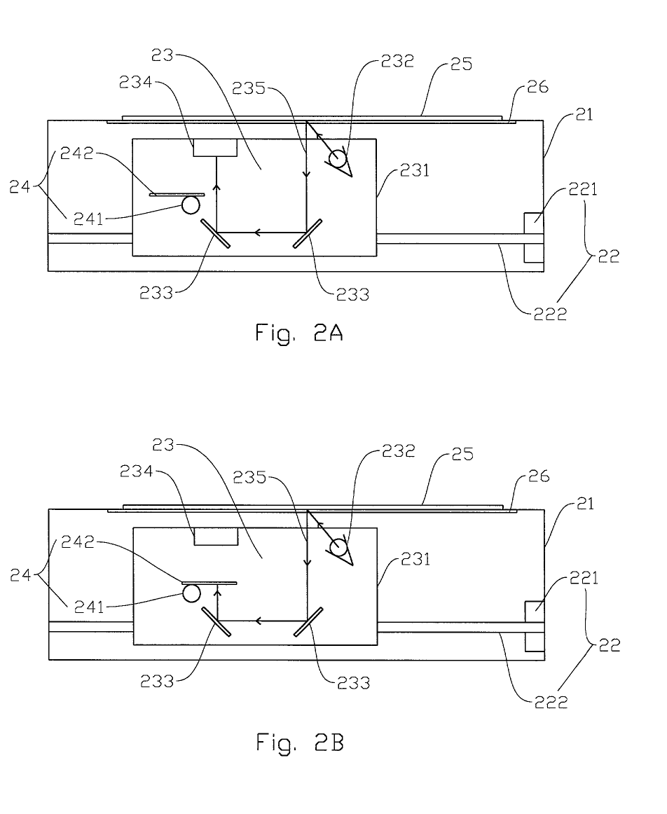

### DETAILED DESCRIPTION OF A PREFERRED EMBODIMENT OF THE INVENTION

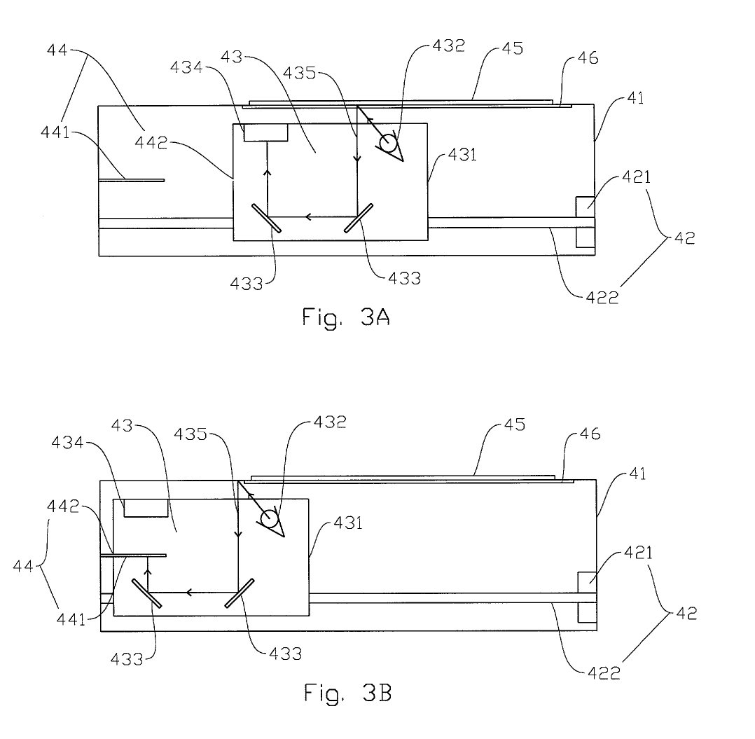

Please refer to FIGS. 3A and 3B, it is shown that a fixed mask is utilized to the present invention. FIG. 3A shows a scanner implemented a fixed mask under the situation that the light is not obstruct by the fixed mask. FIG. 3B shows that the fixed mask obstructs the light in the scanner. The scanner includes a shell 41, a driving module 42, an image capturing module 43 and the fixed mask 44. The shell 41 includes a transparent window 46, such as glass made, for placing a document 45. The driving module 42 is positioned inside the shell 41, mounted on the shell 41 at both ends of the driving module 42. The driving module 42 includes an actuator 421 for providing the driving force, and a guiding rod 422 which is mounted inside the shell by both ends. The actuator 421 may be a motor. The image capturing module 43 is connected to the driving module 42. The driving module is capable of moving the image capturing module 43 along the guiding rod 422 for completing the entire document scan. The image capturing module includes a cover 431, a light source 432 for propagating light, an image sensing element 434 for capturing the image of the document and further transforming the image to digital signals, and plural mirror or reflecting plates 433 for altering the light paths. The image sensing element 434 may be a CCD (Charged Coupled Device). The fixed mask 44 is positioned at a predetermined position. The fixed mask contains a slab 441 that the light cannot pass through. The slab is placed inside the shell 41 and in parallel to the movement of the image capturing module 43 in order to obstruct the light path, specifically, stopping the light from entering the image sensing element. The image capturing module 43 further has an opening 442 for fitting the slab 441. The slab 441 may insert to the image capturing module 43 therefore obstructing the light path 435.

When the scanner is initiated to conduct the scan, as shown in FIG. 3A. The light path 435 of the light is propagated by the light source 432. After the reflections made by document 45 and plural reflecting plates 433, the light is transmitted into the image sensing element 434. The image sensing element 434 therefore outputs digital signals. The image capturing module 43 is moved by the driving module 43 in parallel to the document for completing the document scan.

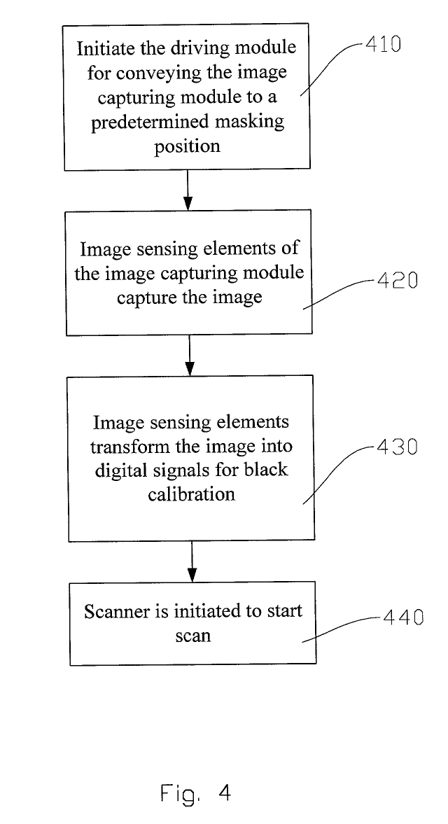

However, before the actual scanning process is started, the black calibration is needed to be done first. Please refer to FIGS. 3B and 4. The driving module 42 of the scanner will drive the image capturing module 43 move to a predetermined masking position in parallel as shown at the step 410. The slab 441 passes the opening then inserts into the image capturing module 43. The light propagated from the light source 432 is therefore obstructed by the slab 441. Thus, the light cannot be transmitted into the image sensing element 434. In this case, the image sensing element 434 starts to generate the black signals therefore the black calibration is conducted. The generated black signals represent the standard black signals as shown at the step 430. After the black calibration is completed, the scanner is ready to conduct the scan.

In view of the above, the present invention doesn't need another conveying module to move the masking device since the mask or the slab is fixed at a predetermined place. The fixed mask may also obstruct the light into the sensing element or a CCD for conducting the black calibration. Comparing to the ordinary scanner, the present invention only needs a little time to warm up, rather than the ordinary scanner needs to turn on and off thus causing lot time to warm up, just waiting the light source is becoming stable. Further, the cost for no utilization of the conveying module was dropped and elimination of the conveying module also reduces the possibilities that the conveying module may break down earlier than other parts. Thus, the present invention achieves lots benefits than ordinary scanners.

Although preferred embodiments of the present invention have been described in the forgoing description and illustrated in the accompanying drawings, it will be understood that the invention is not limited to the embodiments disclosed, but is capable of numerous rearrangements, modifications, and substituting of parts and elements without departing from the spirit and scope of the invention. Accordingly, the present invention is intended to encompass such rearrangements, modifications, and substitutions of parts and elements as fall within the scope of the appended claims.

1. A scanning device comprising:
a shell;
a driving module;
an image capturing module, driven by said driving module for capturing an image of a document, further transforming said image to digital signal; and
a fixed masking module, fixedly mounted inside the shell for obstructing a light path,
wherein said image capturing module is moved by said driving module to a predetermined position where said fixed marking module is mounted, for obstructing said light path, thus black calibration is conducted.

2. The scanning device of claim 1, wherein said shell comprises a transparent window, positioned at an end of said shell for placing said document.

3. The scanning device of claim 2, wherein said transparent window is a glass plate.

4. The scanning device of claim 1, wherein said driving module comprises:
an actuator, positioned at one side of said driving module, for providing a driving force; and
a guiding rod, mounted inside the shell for guiding said image capturing module.

5. The scanning device of claim 4, wherein said actuator is a motor.

6. The scanning device of claim 1, wherein said image capturing module comprises:
a light source for propagating light; and
an image sensing element for capturing said image and transforming said image into digital signals.

7. The scanning device of claim 6, wherein said image sensing element is a charged-couple device (CCD).

8. The scanning device of claim 1, wherein said image capturing module comprises:
a cover; and
plural reflecting plates, positioned inside said shell, for altering said light path.

9. The scanning device of claim 1, wherein said fixed masking module comprises a mask, mounted at a predetermined position, parallel to the movement of said image capturing module for obstructing said light path.

10. The scanning device of claim 1, wherein said image capturing module comprises an opening, formed in said cover for allowing said mask passing through in order to obstruct said light path.

11. The scanning device of claim 9, wherein said mask is not transparent.

12. A method for obstructing a light path by a fixed mask comprising the steps of:
driving an image capturing module to a predetermined position where said fixed mask is mounted, for obstructing said light path into an image sensing element of said image capturing module;
capturing said image by said image sensing element; and
transforming said image to digital signals for completing black calibration.

13. The method of claim 12, wherein said image is a stand black image.

14. The method of claim 12, wherein said predetermined position is a place for a driving module to move said image capturing module to said fixed mask which said light path is obstructed.
